(19) United States
(12) Patent Application Publication
(10) Pub. No.: US 2025/0320632 A1
(43) Pub. Date: Oct. 16, 2025

(54) SUBSTRATE-FUSION TECHNIQUE

(71) Applicant: LUMILEDS LLC, San Jose, CA (US)

(72) Inventor: Hisashi Masui, Newark, CA (US)

(21) Appl. No.: 18/867,682

(22) PCT Filed: Jun. 28, 2023
(86) PCT No.: PCT/US2023/026417

§ 371 Date: Nov. 20, 2024

Related U.S. Application Data
(60) Provisional application No. 63/356,842, filed on Jun. 29, 2022.

(51) Int. Cl. C30B 33/06; C30B 29/16

(52) U.S. Cl. CPC C30B 33/06; C30B 29/16

(57) ABSTRACT

Various examples include a substrate and related method for bonding a first substrate formed from a cubic material to a second substrate formed from a non-cubic material. Other examples include a method of finding crystallographic planes of cubic materials being used as epitaxial substrates for non-cubic material epitaxy. By selecting low-index crystallographic planes, the two-dimensional (2D) repetitive pattern appears as parallelograms which enable epitaxy of non-cubic crystals. For example, an appropriate orientation in GaP has been identified as a substrate to the 0-Ga2O3 0-plane. In other embodiments, the disclosed subject-matter describes a method for determining crystallographic planes of cubic materials for bonding a first substrate formed from the cubic material to a second substrate formed from the non-cubic material. Other methods and techniques are also disclosed.

### CLAIM OF PRIORITY

This patent application claims priority to U.S. Provisional Application Ser. No. 63/356,842, entitled, “SUBSTRATE-FUSION TECHNIQUE,” filed 29 Jun. 2022; the disclosure of which is incorporated herein by reference in its entirety.

### TECHNOLOGY FIELD

The disclosed subject-matter is related generally to the field of epitaxial techniques used on the semiconductor and related industries (e.g., flat panel displays, thin-film heads, etc.). More specifically, in various embodiments, the disclosed subject-matter is related to substrate-fusion techniques related to various types of crystalline and polycrystalline substrates.

### BACKGROUND

Many engineers and researchers in the semiconductor and related industries have considered that growing epitaxial layers on dissimilar crystal-structure substrates would not be feasible. However, if such an epitaxial technique could be established, various types of an increasing number of materials could be grown via epitaxy using commercially-available substrate materials. The commercially-available substrate materials could even be based on different crystallographic orientations, such as, for example, gallium arsenide (GaAs) and silicon (Si). Being able to grow such diverse types of materials can increase device functionalities that semiconductor devices will be able to provide.

Various techniques described herein provide a means to address combining materials having, for example, different crystallographic orientations.

### SUMMARY

This document describes, among other things, a method of finding crystallographic planes of cubic materials being used as epitaxial substrates for non-cubic material epitaxy. By selecting low-index crystallographic planes, the two-dimensional (2D) repetitive pattern appears as parallelograms which enable epitaxy of non-cubic crystals. An appropriate orientation in GaP has been identified as a substrate to the β-Ga2O3 β-plane. In other embodiments, the disclosed subject-matter describes a method for determining crystallographic planes of cubic materials for bonding a first substrate formed from the cubic material to a second substrate formed from the non-cubic material.

In various embodiments, the disclosed subject-matter is a bonded substrate. The bonded substrate includes a first substrate and a second substrate. The first substrate and the second substrate include at least one set of material pairs for the substrate selected from material pairs including silicon on sapphire, gallium nitride (GaN) on sapphire, aluminum gallium indium phosphide (AlGaInP) on gallium arsenide (GaAs), aluminum gallium indium phosphide (AlGaInP) on diamond, aluminum gallium indium phosphide (AlGaInP) on iridium, and graphene on hexagonal boron nitride (hBN).

In various embodiments, the disclosed subject-matter is a bonded substrate. The bonded substrate includes a first substrate formed from a cubic material to a second substrate formed from a non-cubic material. A lattice mismatch between the cubic material and the non-cubic material is less than about 1%.

In various embodiments, the disclosed subject-matter is a method for determining crystallographic planes of a cubic material to be used as an epitaxial substrate for a non-cubic material epitaxy. The method includes determining a lattice mismatch between two dissimilar materials for the cubic material and the non-cubic material; selecting low-index crystallographic planes, including selecting a {1 [symbol] [symbol] } plane with k being about equal to [symbol] and [symbol] and [symbol] are not limited to integers, the selecting the low-index crystallographic planes to reduce the lattice mismatch; and determining a second lattice mismatch based on the selected low-index crystallographic planes.

In various embodiments, the disclosed subject-matter is a method for determining crystallographic planes of a cubic material to be used as an epitaxial substrate for a non-cubic material epitaxy. The method includes determining a lattice mismatch between two dissimilar materials for the cubic material and the non-cubic material; selecting low-index crystallographic planes, including selecting a {1 [symbol] [symbol] } plane with [symbol] not being equal to [symbol] , and [symbol] is only approximately equal to [symbol] , and [symbol] and [symbol] are not limited to integers, the selecting the low-index crystallographic planes to reduce the lattice mismatch; and determining a second lattice mismatch based on the selected low-index crystallographic planes.

In various embodiments, the disclosed subject-matter is a method for determining crystallographic planes of cubic materials for bonding a first substrate formed from a cubic material to a second substrate formed from a non-cubic material. The method includes determining a lattice mismatch between two dissimilar materials for the cubic material and the non-cubic material; selecting low-index crystallographic planes, including selecting a {1 [symbol] [symbol] } plane with k being about equal to [symbol] , and [symbol] and [symbol] are not limited to integers, the selecting the low-index crystallographic planes to reduce the lattice mismatch; and determining a second lattice mismatch based on the selected low-index crystallographic planes.

In various embodiments, the disclosed subject-matter is a method for determining crystallographic planes of cubic materials for bonding a first substrate formed from the cubic material to a second substrate formed from a non-cubic material. The method includes determining a lattice mismatch between two dissimilar materials for the cubic material and the non-cubic material; selecting low-index crystallographic planes, including selecting a {1 [symbol] [symbol] } plane with [symbol] not being equal to [symbol] , and [symbol] is only approximately equal to [symbol] , and [symbol] and [symbol] are not limited to integers, the selecting the low-index crystallographic planes to reduce the lattice mismatch; and determining a second lattice mismatch based on the selected low-index crystallographic planes.

### BRIEF DESCRIPTION OF FIGURES

Various ones of the appended drawings merely illustrate example implementations of the present disclosure and should not be considered as limiting its scope.

FIG. 1 shows an example of a unit cell of a beta-gallium oxide (β-Ga₂O₃) crystal structure, as is used in accordance with various embodiments of the disclosed subject-matter;

FIG. 2 shows an exemplary relationship between surface orientation of a Ga₂O₃ substrate and homoepitaxial growth rate of various crystal orientations;

FIG. 3A shows an example of a cut of a unit cube of a Ga₂O₃ crystal resulting in a rhombus plane;

FIG. 3B shows the resulting rhombus plane of FIG. 3A for a β-plane of a Ga₂O₃ crystal, in accordance with various exemplary embodiments of the disclosed subject-matter;

FIG. 4A shows an example of a cut of a unit cube of a gallium phosphide (GaP) crystal resulting in a parallelogram plane;

FIG. 4B shows the resulting parallelogram plane of FIG. 4A near a (112) plane of a GaP crystal, in accordance with various exemplary embodiments of the disclosed subject-matter; and

FIG. 5 shows a comparison of the β-plane of a Ga₂O₃ crystal of FIG. 3B and the (112) plane of a GaP crystal of FIG. 4B; in accordance with various embodiments of the disclosed subject-matter.

### DETAILED DESCRIPTION

The disclosed subject-matter is directed to heteroepitaxy techniques related to various types of crystalline and polycrystalline substrates. The disclosed subject-matter described shows that a suitable crystallographic orientation of a cubic material used for monoclinic crystal-growth and substrate-fusion that can be incorporated into various types of semiconductor integrated circuit devices. Although certain specific examples are provided herein so as to better describe various embodiments, the disclosed subject-matter can be extended readily to generic materials that are not explicitly discussed herein.

Further, the techniques described herein may be applied both to epitaxial techniques and various types of substrate-fusion techniques (e.g., wafer fusion or wafer bonding).

In homoepitaxy the growth layers are made up of the same material as the substrate, while in heteroepitaxy, the growth layers are of a material different from the substrate. Heteroepitaxy is therefore a special case of heterogeneous nucleation in which a distinct crystallographic-relationship exists between orientations of crystals in a substrate and a material which is deposited on the substrate. Heteroepitaxy is therefore a specialized type of epitaxy performed with materials that are different from each other.

In heteroepitaxy, a crystalline film grows on a crystalline substrate or film of a different material. This technology is often used to grow crystalline films of materials for which crystals cannot otherwise be obtained and to fabricate integrated crystalline layers of different materials. Examples include silicon on sapphire, gallium nitride (GaN) on sapphire, aluminum gallium indium phosphide (AlGaInP) on gallium arsenide (GaAs) or diamond or iridium, and graphene on hexagonal boron nitride (hBN).

Heteroepitaxy occurs when a film of different composition and/or crystal structure than the substrate is grown. In this case, the amount of strain in the film is determined by the lattice mismatch c, where

$$ε = \frac{{a}_{f} - {a}_{s}}{{a}_{f}}$$

and a_{f} and a_{f} are lattice constants of the film and a substrate upon which the film is grown. In various embodiments, the film and the substrate may have similar lattice spacings. However, the film and the substrate may have substantially different coefficients of thermal expansion (CTE), as is described in more detail below.

Cubic and hexagonal semiconductor materials have been utilized for many years (e.g., silicon (Si), gallium arsenide (GaAs), gallium nitride (GaN), etc.) in the semiconductor and related industries. Various types of materials are anticipated to be used in the future but various drawbacks are currently encountered, such as poor thermal conductivity issues, as described in more detail below. However, such anticipated future materials include semiconductor materials with less common crystallographic structures (e.g., gallium oxide (Ga₂O₃)). Ga₂O₃ includes electrical characteristic advantages of, for example, an ultrawide bandgap as a semiconductor material and a high-breakdown electric field. Conventional epitaxy to fabricate device structures is either homoepitaxy (where epi substrates comprise the same materials as the grown materials (e.g., Si films formed on Si substrates)) or hetero-epitaxy using epitaxial substrates having the same or similar crystal structure as the materials grown on those substrates (e.g., cubic GaAs for cubic aluminum indium gallium phosphide (AlInGaP) epitaxial layers, hexagonal sapphire for hexagonal GaN, etc.). However, hetroepitaxy using a substrate of dissimilar crystal structure has not been considered for a variety of semiconductor materials.

Gallium phosphide (GaP), a phosphide of gallium, is a compound semiconductor material with an indirect band gap of 2.24 eV at room temperature. Gallium phosphide is used in manufacturing low-cost red, orange, and green light-emitting diodes (LEDs) with low to medium brightness levels.

Gallium trioxide (Ga₂O₃); β-Ga₂O₃ is an emerging, ultra-wide bandgap (energy gap of 4.85 eV) transparent semiconducting-oxide. β-Ga₂O₃ crystals exhibit interesting scientific properties. They can be either insulators or conductors, depending on the growth conditions. Consequently, a Ga₂O₃ semiconductor is anticipated to be a choice for a next generation of high-power devices. Research-level devices have been demonstrated via homoepitaxy where Ga₂O₃ substrates are used. However, a major disadvantage of the Ga₂O₃ crystal is known to be its poor thermal conductivity that restricts device performances. The thermal conductivity and the coefficient of thermal expansion (CTE) is shown in Table I, below.

TABLE I
Material Thermal Properties

| | Thermal Conductivity | |
|---|---|---|
| Material | [W/m · K] | CTE [ppm] |
| β-Ga₂O₃ | 12 | 4-8 |
| GaP | 110 | 4.5 |
| Si | 130 | 2.6 |
| Sapphire | 46 | 8 |
| AlN (ceramic) | 300 | 5 |
| β-Ga₂O₃ (ceramic) | 29 | 6 |

Since Ga₂O₃ has a low thermal conductivity (12 W/m·K) as compared with may common semiconductor materials (e.g., GaP at 110 W/m·K, Si at 130 W/m·K, or AlN at 300 W/m·K), researchers have considered that Ga₂O₃ is not a good choice for various integrated circuit devices, especially high-power devices, due to the poor heat conduction of Ga₂O₃. Although devices have been grown homoepitaxially on the β-plane of Ga₂O₃, the general concern is that Ga₂O₃, especially using Ga₂O₃ as an epitaxial substrate, is a poor heat conductor. Consequently, the lack of consideration for integrated circuit devices for Ga₂O₃ exists despite the electrical characteristics of ultrawide bandgap as a semiconductor material and a high-breakdown electric field.

As disclosed herein, the use of Ga₂O₃ can be considered in various conditions. For example, in various embodiments, Ga₂O₃ materials can be used in integrated circuit devices if the deposition of a grown film is thin. Upon reading and understanding the disclosed subject-matter, a person of ordinary skill in the art will recognize how the term “thin” should be defined for a given integrated circuit device. In various embodiments, Ga₂O₃ can be used along particular crystallographic planes.

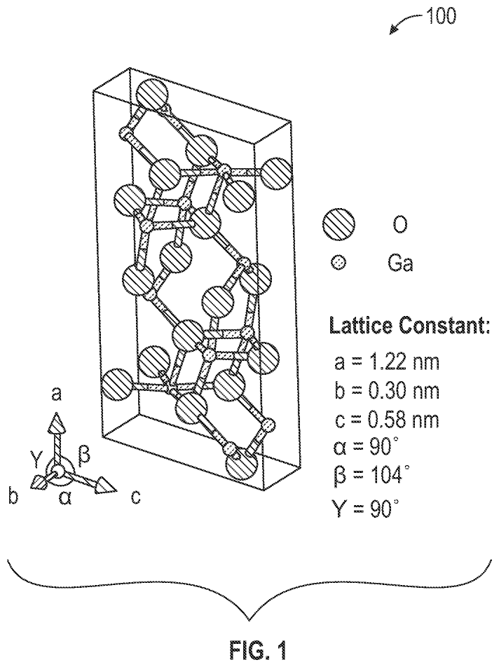

FIG. 1 shows an example of a unit cell 100 of a beta-gallium oxide (0-Ga₂O₃) crystal structure, as is used in accordance with various embodiments of the disclosed subject-matter. Ga₂O₃ has a monoclinic lattice. A monoclinic system is one of the structural categories to which crystalline solids can be assigned. Crystals in this system are referred to three axes of unequal lengths-say, a, b, and c—of which a is perpendicular to b and c, but b and c are not perpendicular to each other. In crystallography, the monoclinic crystal system is one of the seven crystal systems. A crystal system is described by three vectors. In the monoclinic system, the crystal is described by vectors of unequal lengths, as in the orthorhombic system. They form a rectangular prism with a parallelogram as its base. Hence two pairs of vectors are perpendicular (meet at right angles), while the third pair makes an angle other than 90°.

In the triclinic system, the crystal is described by vectors of unequal length, as in the orthorhombic system. In addition, the angles between these vectors must all be different and may not include 90°.

With reference again to FIG. 1 and for the unit cell 100 shown, the lattice constants and respective angles are shown in Table II, below.

TABLE II
Lattice Constants for β-Ga₂O₃
β-Ga₂O₃
Lattice Constants

| | |
|---|---|
| a = 1.22 nm | α = 90° |
| b = 0.30 nm | β = 104° |
| c = 0.58 nm | γ = 90° |

Further, among possible epitaxy orientations, the {0 1 0} orientation (the β-plane) has been found to have an advantage of fast epitaxial growth rate.

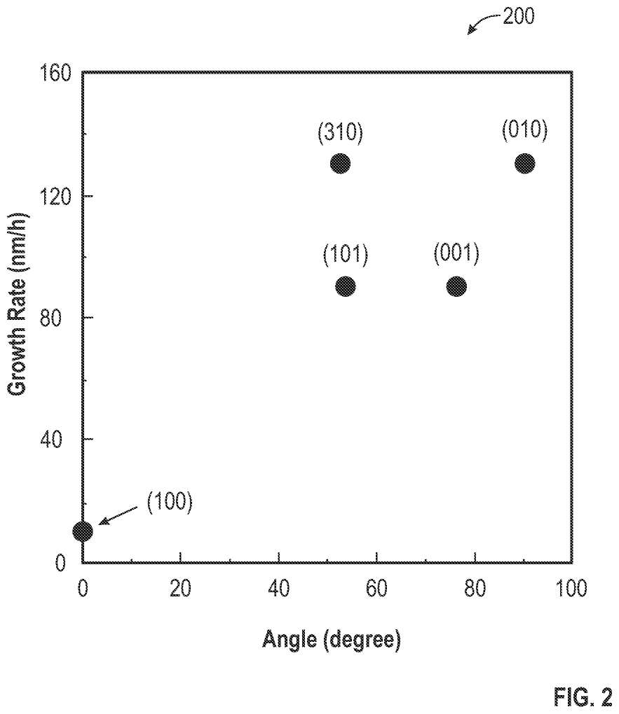

For example, with reference now to FIG. 2, an exemplary relationship in a graph 200 between surface orientation of a Ga₂O₃ substrate and homoepitaxial growth rate (in nm per hour) as a function of the angle between the surface of the substrate and the (100) plane, for various crystal orientations is shown.

As described above, growing epitaxial layers on dissimilar crystal-structure substrates has been considered to not be feasible. Consequently, performing epitaxy on dissimilar crystal-structure substrates has not been attempted, especially for commercialization of devices fabricated from such dissimilar materials. Nevertheless, as disclosed herein, establishing such an epitaxial technique, various additional materials may be epitaxially formed using, for example, commercially-available substrate materials (but in different crystallographic orientations) such as GaAs and Si. Using these techniques can increase a level of device functionality from semiconductor devices.

In the example of Ga₂O₃ described above and with continuing reference to Table I, the poor thermal conductivity of Ga₂O₃ is inherent. Therefore, the disclosed subject-matter describes to grow device structures using hetero-epitaxy. As described in more detail below, as a popular growth plane is the parallelogram β-plane, it is nontrivial to find a good thermally-conducting substrate with a matching lattice.

As described above, growing epitaxial layers on dissimilar crystal-structure substrates has been considered to not be feasible. Consequently, performing epitaxy on dissimilar crystal-structure substrates has not been attempted, especially for commercialization of devices fabricated from such dissimilar materials. Nevertheless, as disclosed herein, establishing such an epitaxial technique, various additional materials may be epitaxially formed using, for example, commercially-available substrate materials (but in different crystallographic orientations) such as GaAs and Si. Using these techniques can increase a level of device functionality from semiconductor devices.

In the example of Ga₂O₃ described above and with continuing reference to Table I, the poor thermal conductivity of Ga₂O₃ is inherent. Therefore, the disclosed subject-matter describes to grow device structures using hetero-epitaxy. As described in more detail below, as a popular growth plane is the parallelogram β-plane, it is nontrivial to find a good thermally-conducting substrate with a matching lattice.

The disclosed subject-matter provides a method of finding crystallographic planes of cubic materials being used as epitaxial substrates for non-cubic material epitaxy. By selecting low-index crystallographic planes, the two-dimensional (2D) repetitive pattern appears as parallelograms which enable epitaxy of non-cubic crystals. An appropriate orientation in GaP has been identified as a substrate to the β-Ga₂O₃ β-plane.

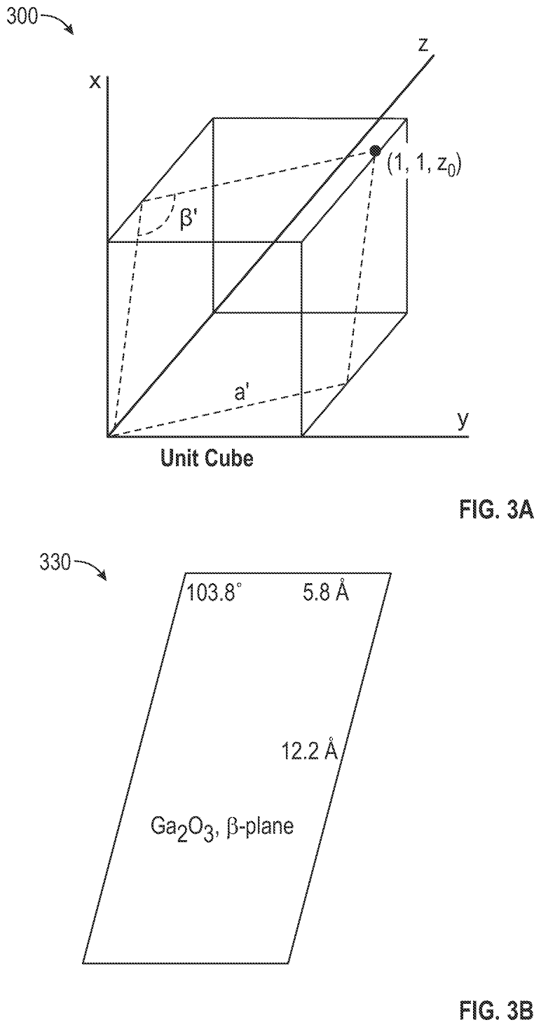

FIG. 3A shows an example of a cut of a unit cube 300 of a Ga₂O₃ crystal resulting in a rhombus plane. In this embodiment, when a cubic crystal is cut in such a way shown in FIG. 3A, the cut surface of the crystal has a 2D repetitive pattern of a rhombus (see a rhombus plane 300 with reference to FIG. 3B, below). Such a surface allows a rhombohedral crystal to grow in its low-index plane, given that the lattice constants approximately match. Matching the lattice constant depends on a choice of substrate and epitaxial materials. A rhombus is a primitive cell of a hexagonal pattern, thus such a plane may also allow a hexagonal crystal to grown in its low-index plane, by approximately matching the lattice constants. Lattice mismatches of various hetero systems is shown below with reference to Table V. As indicated, the material combinations of β-Ga₂O₃ and GaP can have a lattice mismatch of 1.0% or less.

FIG. 3B shows the resulting rhombus plane 330 of FIG. 3A for a β-plane of a Ga₂O₃ crystal, in accordance with various exemplary embodiments of the disclosed subject-matter.

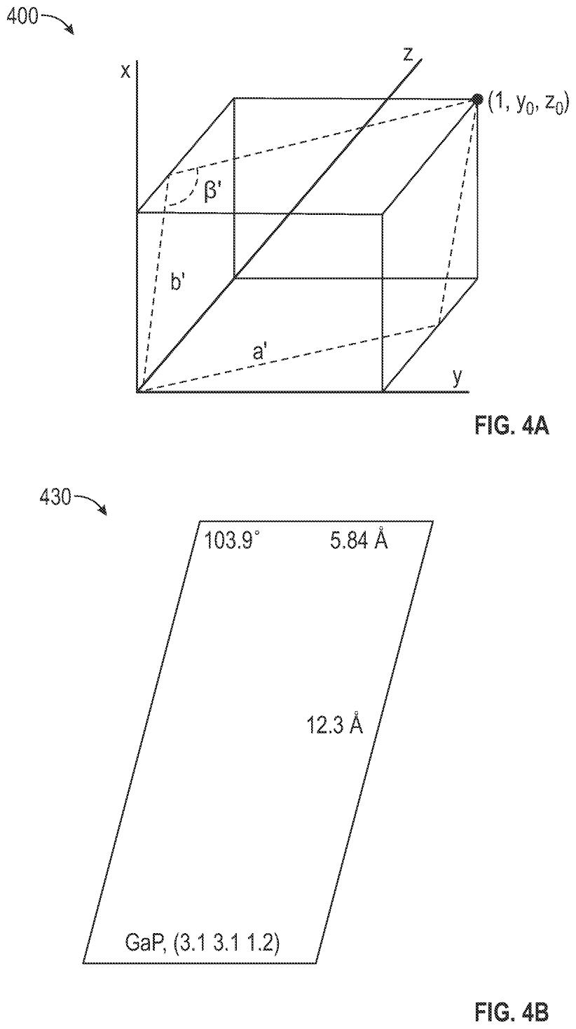

FIG. 4A shows an example of a cut of a unit cube 400 of a gallium phosphide (GaP) crystal resulting in a parallelogram plane 430 (see FIG. 4B). FIG. 4B shows the resulting parallelogram plane 430 of FIG. 4A near a (112) plane of a GaP crystal, in accordance with various exemplary embodiments of the disclosed subject-matter. A surface of the parallelogram plane 430 allows a triclinic crystal to grow in its low index plane, given that the lattice constants approximately match. The triclinic crystal is the lowest symmetry of the crystal. The {2 2 1} plane of a cubic crystal (e.g., GaP) is close to the parallelogram plane 430.

Consequently, the method of the disclosed subject-matter for finding a substrate can apply to any crystals, given that the lattice constants approximately match. As will be recognized by a person of ordinary skill in the art, upon reading and understanding the disclosed subject-matter, Miller indices of a cutting orientation can be found using common crystallography knowledge.

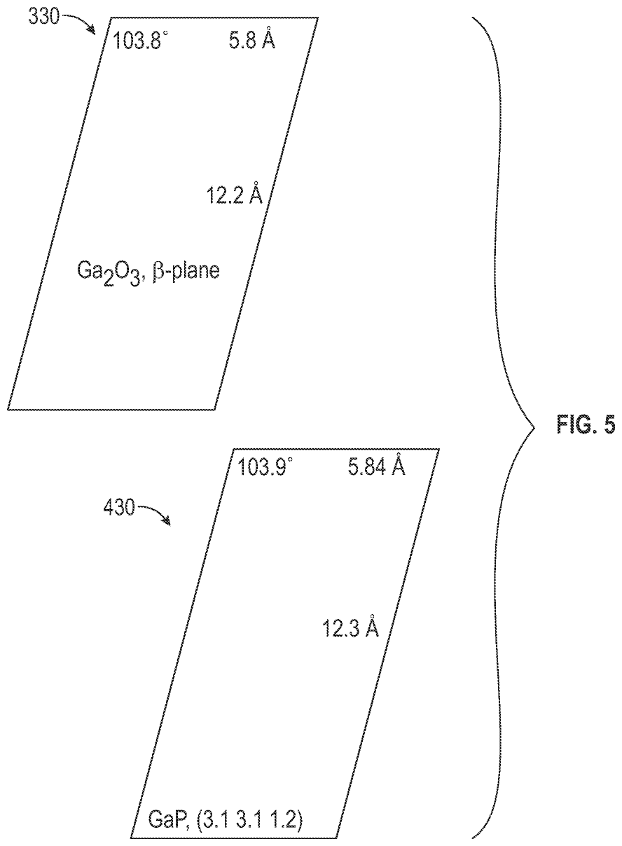

FIG. 5 shows a comparison of the β-plane of a Ga₂O₃ crystal of FIG. 3B (the rhombus plane 330) and the (1 1 2) plane of a GaP crystal of FIG. 4B (the parallelogram plane 430); in accordance with various embodiments of the disclosed subject-matter. Approximate lattice constants and other material information for the two planes 330, 430 are shown with reference to Table III and Table IV, below. The terms y₀ and z₀ in Table IV are cubic coordinates that satisfy a GaP plane lattice-matching to the β-Ga₂O₃ plane.

TABLE III
Ga₂O₃ β-Plane
(a_{Ga2O3} = 5.65 Å)

a = 12.2 Å
b = 3.04 Å
c = 5.80 Å
β = 103.8°

TABLE IV
GaP (a_{GaP} = 5.45 Å)

| | |
|---|---|
| y₀, z₀ | 2.1, 1.2 |
| plane | {1/3.1 1/3.1 1/1.2} = {1 1 2.6} |
| a′ | 5.84 Å |
| b′ | 12.3 Å |
| β′ | 103.9° |

For the Ga₂O₃ example, disclosed subject-matter indicates that the [1 1 2.6] orientation of GaP lattice-matches to the R-plane of b-Ga₂O₃ with less than a 1% of mismatch as shown in Table V, below. Thus, hetero epitaxy of β-Ga₂O₃ on thermally conductive GaP becomes feasible.

TABLE V
Lattice Mismatch of Various Hetero Systems

| Material Combinations | Lattice Mismatch [%] |
|---|---|
| GaN on Sapphire | 16 |
| AlInGaP(GaAs) and GaP | 3.6 |
| GaN and Si | 17 |
| β-Ga₂O₃ and GaP | 1.0 or less |

As disclosed herein, the growth of monoclinic crystals in a non-rectangular orientation can be provided on non-cubic material as an epitaxial process with consideration to the substrates including:
(1) The {1 [symbol] [symbol] } plane where [symbol] = [symbol] (or where the two indices are about equal to each other), and and [symbol] and [symbol] are not limited to integers. For a zincblende structure, both “A” and “B” orientations are included in considering the plane.
(2) The vicinity planes of (1), above, including vicinity planes of {1 [symbol] -δ₁ [symbol] -δ₂} where δ₁ and δ₂ comprise small values. Small values may comprise, for example, values of about 0.0 to about 0.1. These small values comprising vicinity planes are commonly referred to as “miscuts” or “offcuts.” In various embodiments, the values of δ₁ and δ₂ are about equal to each other.
(3) Vicinity planes of (1) or (2) above where [symbol] ≠ [symbol] , but [symbol] 18 [symbol] (e.g., an offcut). In various embodiments, [symbol] ˜ [symbol] can be characterized as a difference between [symbol] and [symbol] as being within a value of about 0.1.
(4) Each of the growth considerations shown above may be assisted, in various embodiments, with a low-temperature (LT) nucleation layer for forthcoming crystal growth. In embodiments, the low-temperature growth may be similar to GaN-on-sapphire growth. For example, in an embodiment comprising GaN-on-sapphire, case the low temperature designates a temperature range from about 450° C. to about 650° C. In general, low temperature can be considered as being about 350° C. below a normal growth temperature for obtaining a single-crystal semiconductor material.

As disclosed herein, the growth of crystals (not necessarily monoclinic crystals) in a non-rectangular orientation can be provided on non-cubic material as an epitaxial process with consideration to the substrates including:
(1) The {1 [symbol] [symbol] } plane where [symbol] and [symbol] are not limited to integers. For a zincblende structure, both “A” and “B” orientations are included in considering the plane.
(2) The growth considerations shown above may be assisted, in various embodiments, with a low-temperature (LT) nucleation layer for forthcoming crystal growth. In embodiments, the low-temperature growth may be similar to GaN-on-sapphire growth.

The disclosed subject-matter described herein can readily be applied to various types of substrate-fusion techniques (e.g., wafer fusion or wafer bonding). Substrate-fusion of monoclinic-crystal device structures in a non-rectangular orientation can be provided on cubic material substrates with consideration to the substrates including:
(1) The {1 [symbol] [symbol] } plane where [symbol] = [symbol] (or about equal to), and [symbol] and [symbol] are not limited to integers. For a zincblende structure, both “A” and “B” orientations are included in considering the plane.
(2) The vicinity planes of (1), above, including vicinity planes of {1 [symbol] -δ₁ [symbol] -δ₂} where δ₁ and δ₂ comprise small values. These small value comprising vicinity planes are commonly referred to as “miscuts” or “offcuts.”
(3) Vicinity planes of (1) or (2) above where [symbol] ≠ [symbol] but [symbol] ˜ [symbol] (e.g., an offcut).

As disclosed herein, substrate-bonding of device structures in a non-rectangular orientation can be provided on cubic material substrates with consideration to the substrates including:
(1) The {1 [symbol] [symbol] } plane where [symbol] and [symbol] are not limited to integers. For a zincblende structure, both “A” and “B” orientations are included in considering the plane.

As described herein, the disclosed subject-matter provides a method of finding crystallographic planes of cubic materials being used as epitaxial substrates for non-cubic material epitaxy. By selecting low-index crystallographic planes, the two-dimensional (2D) repetitive pattern appears as parallelograms which enable epitaxy of non-cubic crystals. An appropriate orientation in GaP has been identified as a substrate to the β-Ga₂O₃ β-plane.

As used herein, the term “or” may be construed in an inclusive or exclusive sense. Further, other embodiments will be understood by a person of ordinary skill in the art based upon reading and understanding the disclosure provided. Moreover, the person of ordinary skill in the art will readily understand that various combinations of the techniques and examples provided herein may all be applied in various combinations.

Throughout this specification, plural instances may implement components, operations, or structures described as a single instance. Although individual operations are illustrated and described as separate operations, one or more of the individual operations may be performed concurrently, and, unless otherwise stated, nothing requires that the operations necessarily be performed in the order illustrated. Structures and functionality presented as separate components in example configurations may be implemented as a combined structure or component. Similarly, structures and functionality presented as a single component may be implemented as separate components. These and other variations, modifications, additions, and improvements fall within the scope of the subject matter described herein.

Further, although not shown explicitly but understandable to a skilled artisan, each of the various arrangements, quantities, and number of elements may be varied (e.g., the particular types of elemental and compound materials). Moreover, each of the examples shown and described herein is merely representative of one possible configuration and should not be taken as limiting the scope of the disclosure.

Although various embodiments are discussed separately, these separate embodiments are not intended to be considered as independent techniques or designs. As indicated above, each of the various portions may be inter-related and each may be used separately or in combination with other embodiments discussed herein. For example, although various embodiments of operations, systems, and processes have been described, these methods, operations, systems, and processes may be used either separately or in various combinations.

Consequently, many modifications and variations can be made, as will be apparent to a person of ordinary skill in the art upon reading and understanding the disclosure provided herein. Functionally equivalent methods and devices within the scope of the disclosure, in addition to those enumerated herein, will be apparent to the skilled artisan from the foregoing descriptions. Portions and features of some embodiments may be included in, or substituted for, those of others. Such modifications and variations are intended to fall within a scope of the appended claims. Therefore, the present disclosure is to be limited only by the terms of the appended claims, along with the full scope of equivalents to which such claims are entitled. It is also to be understood that the terminology used herein is for the purpose of describing particular embodiments only and is not intended to be limiting.

The Abstract of the Disclosure is provided to allow the reader to ascertain quickly the nature of the technical disclosure. The abstract is submitted with the understanding that it will not be used to interpret or limit the claims. In addition, in the foregoing Detailed Description, it may be seen that various features may be grouped together in a single embodiment for the purpose of streamlining the disclosure. This method of disclosure is not to be interpreted as limiting the claims. Thus, the following claims are hereby incorporated into the Detailed Description, with each claim standing on its own as a separate embodiment.

The description provided herein includes illustrative examples, devices, and apparatuses that embody various aspects of the matter described in this document. In the description, for purposes of explanation, numerous specific details are set forth in order to provide an understanding of various embodiments of the matter discussed. It will be evident however, to those of ordinary skill in the art, that various embodiments of the disclosed subject-matter may be practiced without these specific details. Further, well-known structures, materials, and techniques have not been shown in detail, so as not to obscure the various illustrated embodiments. As used herein, the terms “about,” “approximately,” and “substantially” may refer to values that are, for example, within ±10% of a given value or range of values.

THE FOLLOWING NUMBERED EXAMPLES ARE SPECIFIC EMBODIMENTS OF THE DISCLOSED SUBJECT-MATTER

Example 1: In an exemplary embodiment, the disclosed subject-matter is a bonded substrate. The bonded substrate includes a first substrate formed from a cubic material and a second substrate formed from a non-cubic material. The first substrate has a low-index crystallographic plane with a {1 [symbol] [symbol] } plane with [symbol] being about equal to [symbol] , and [symbol] and [symbol] are not limited to integers.

Example 2: The bonded substrate of Example 1, wherein a lattice mismatch between the first substrate and the second substrate is less than about 1%.

Example 3: The bonded substrate of either of the preceding Examples, wherein the first substrate and the second substrate include at least one set of material pairs selected from material pairs including silicon on sapphire, gallium nitride (GaN) on sapphire, aluminum gallium indium phosphide (AlGaInP) on gallium arsenide (GaAs), aluminum gallium indium phosphide (AlGaInP) on diamond, aluminum gallium indium phosphide (AlGaInP) on iridium, and graphene on hexagonal boron nitride (hBN).

Example 4: The bonded substrate of any one of the preceding Examples, wherein at least the first substrate includes a semiconductor material with a crystallographic structure formed from gallium oxide (Ga₂O₃).

Example 5: The bonded substrate of any one of the preceding Examples, wherein a lattice mismatch between two dissimilar materials for the cubic material and the non-cubic material is less than about 1%.

Example 6: The bonded substrate of any one of the preceding Examples, wherein at least one of the first substrate and the second substrate is formed from low-index crystallographic planes, wherein a two-dimensional (2D) repetitive pattern appears as parallelograms thereby enabling additional epitaxy of non-cubic crystals.

Example 7: In an exemplary embodiment, the disclosed subject-matter is a method for bonding a first substrate formed from a cubic material to a second substrate formed from a non-cubic material. The method includes determining crystallographic planes of the cubic material; determining a lattice mismatch between two dissimilar materials for the cubic material and the non-cubic material; selecting low-index crystallographic planes, including selecting a {1 [symbol] [symbol] } plane with [symbol] not being equal to [symbol] , and [symbol] is only approximately equal to [symbol] , and [symbol] and [symbol] are not limited to integers, the selecting of the low-index crystallographic planes to reduce the lattice mismatch to less than about 1%; and determining a second lattice mismatch based on the selected low-index crystallographic planes.

Example 8: The method of Example 7, further comprising determining vicinity planes similar to the low-index crystallographic planes, the vicinity planes include {1 [symbol] -δ₁ [symbol] -δ₂}, where δ₁ and δ₂ comprise small values.

Example 9: The method of Example 8, wherein the small values are in a range of about 0.0 to about 0.1.

Example 10: The method of Example 8, wherein the values of δ₁ and δ₂ are about equal to each other.

Example 11: The method of any one of Example 7 through Example 10, wherein both “A” and “B” orientations of a zincblende structure are included in the selecting of the low-index crystallographic planes.

Example 12: The method of any one of Example 7 through Example 11, further comprising forming a low-temperature (LT) nucleation layer on at least one of the first substrate and the second substrate prior to forming a subsequent epitaxial layer.

Example 13: In an exemplary embodiment, the disclosed subject-matter is a bonded substrate. The bonded substrate includes a first substrate and a second substrate. The first substrate and the second substrate include at least one set of material pairs for the substrate selected from material pairs including silicon on sapphire, gallium nitride (GaN) on sapphire, aluminum gallium indium phosphide (AlGaInP) on gallium arsenide (GaAs), aluminum gallium indium phosphide (AlGaInP) on diamond, aluminum gallium indium phosphide (AlGaInP) on iridium, and graphene on hexagonal boron nitride (hBN).

Example 14: The bonded substrate of Example 13, wherein a lattice mismatch between the first substrate and the second substrate is less than about 1%.

Example 15: The bonded substrate of either of Example 13 or Example 14, wherein the first substrate has a low-index crystallographic plane with a {1 [symbol] [symbol] } plane with [symbol] being about equal to [symbol] , with [symbol] and [symbol] not being limited to integers.

Example 16: The bonded substrate of any one of Example 13 through Example 15, wherein at least the first substrate includes a semiconductor material with a crystallographic structure formed from gallium oxide (Ga₂O₃).

Example 17: The bonded substrate of any one of Example 13 through Example 16, wherein a lattice mismatch between two dissimilar materials for the cubic material and the non-cubic material is less than about 1%.

Example 18: The bonded substrate of any one of Example 13 through Example 17, wherein at least one of the first substrate and the second substrate is formed from low-index crystallographic planes, wherein a two-dimensional (2D) repetitive pattern appears as parallelograms thereby enabling additional epitaxy of non-cubic crystals.

1-18. (canceled)

19. A bonded substrate comprising:
a first substrate formed from a cubic material, the first substrate having a low-index crystallographic plane with a {1 [symbol] [symbol] } plane with [symbol] being about equal to [symbol] , with [symbol] and [symbol] not being limited to integers; and
a second substrate formed from a non-cubic material, at least the first substrate including a semiconductor material with a crystallographic structure formed from gallium oxide (Ga₂O₃).

20. The bonded substrate of claim 19, wherein a lattice mismatch between the first substrate and the second substrate is less than about 1%.

21. The bonded substrate of claim 19, wherein the first substrate and the second substrate include at least one set of material pairs selected from material pairs including silicon on sapphire, gallium nitride (GaN) on sapphire, aluminum gallium indium phosphide (AlGaInP) on gallium arsenide (GaAs), aluminum gallium indium phosphide (AlGaInP) on diamond, aluminum gallium indium phosphide (AlGaInP) on iridium, and graphene on hexagonal boron nitride (hBN).

22. The bonded substrate of claim 19, wherein a lattice mismatch between two dissimilar materials for the cubic material and the non-cubic material is less than about 1%.

23. The bonded substrate of claim 19, wherein at least one of the first substrate and the second substrate is formed from low-index crystallographic planes, wherein a two-dimensional (2D) repetitive pattern appears as parallelograms thereby enabling additional epitaxy of non-cubic crystals.

24. A method for bonding a first substrate formed from a cubic material to a second substrate formed from a non-cubic material, the method comprising:
determining crystallographic planes of the cubic material;
determining a lattice mismatch between two dissimilar materials for the cubic material and the non-cubic material;
selecting low-index crystallographic planes, including selecting a {1 [symbol] [symbol] } plane with [symbol] not being equal to [symbol] , and [symbol] is only approximately equal to [symbol] , and [symbol] and [symbol] are not limited to integers, the selecting of the low-index crystallographic planes to reduce the lattice mismatch to less than about 1%; and
determining a second lattice mismatch based on the selected low-index crystallographic planes, at least the first substrate including a semiconductor material with a crystallographic structure formed from gallium oxide (Ga₂O₃).

25. The method of claim 24, further comprising determining vicinity planes similar to the low-index crystallographic planes, the vicinity planes include {1 [symbol] -δ₁ [symbol] -δ₂}, where δ₁ and δ₂ comprise small values.

26. The method of claim 25, wherein the small values are in a range of about 0.0 to about 0.1.

27. The method of claim 25, wherein the values of δ₁ and δ₂ are about equal to each other.

28. The method of claim 24, wherein both “A” and “B” orientations of a zincblende structure are included in the selecting of the low-index crystallographic planes.

29. The method of claim 24, further comprising forming a low-temperature (LT) nucleation layer on at least one of the first substrate and the second substrate prior to forming a subsequent epitaxial layer.

30. A bonded substrate comprising:
a first substrate and a second substrate, the first substrate and the second substrate include at least one set of material pairs for the substrate selected from material pairs including silicon on sapphire, gallium nitride (GaN) on sapphire, aluminum gallium indium phosphide (AlGaInP) on gallium arsenide (GaAs), aluminum gallium indium phosphide (AlGaInP) on diamond, aluminum gallium indium phosphide (AlGaInP) on iridium, and graphene on hexagonal boron nitride (hBN), at least the first substrate including a semiconductor material with a crystallographic structure formed from gallium oxide (Ga₂O₃).

31. The bonded substrate of claim 30, wherein a lattice mismatch between the first substrate and the second substrate is less than about 1%.

32. The bonded substrate of claim 30, wherein the first substrate has a low-index crystallographic plane with a {1 [symbol] [symbol] } plane with [symbol] being about equal to [symbol] , with [symbol] and [symbol] not being limited to integers.

33. The bonded substrate of claim 30, wherein a lattice mismatch between two dissimilar materials for the cubic material and the non-cubic material is less than about 1%.

34. The bonded substrate of claim 30, wherein at least one of the first substrate and the second substrate is formed from low-index crystallographic planes, wherein a two-dimensional (2D) repetitive pattern appears as parallelograms thereby enabling additional epitaxy of non-cubic crystals.
